(19) United States
(12) Patent Application Publication
(10) Pub. No.: US 2021/0335598 A1
(43) Pub. Date: Oct. 28, 2021

(54) PROCESSING METHOD AND SUBSTRATE PROCESSING APPARATUS

(71) Applicant: Tokyo Electron Limited, Tokyo (JP)

(72) Inventors: Takahiro Tokuo, Kurokawa-gun (JP); Shota Yoshimura, Kurokawa-gun (JP); Shinya Morikita, Kurokawa-gun (JP)

(21) Appl. No.: 17/240,101

(22) Filed: Apr. 26, 2021

(30) Foreign Application Priority Data
Apr. 27, 2020 (JP) 2020-078482

(51) Int. Cl. H01L 21/02; H01L 21/311; H01L 21/3065; H01L 21/687; H01J 37/32

(52) U.S. Cl. CPC H01L 21/0262; H01L 21/31144; H01J 37/32449; H01L 21/3065; H01L 21/68714; H01L 21/31116

(57) ABSTRACT

A processing method of a substrate includes placing the substrate having a mask film; forming a deposit on the mask film by plasma of a processing gas which includes a first gas and a second gas and in which a flow rate ratio R1 of the first gas to the second gas is controlled; and removing a part of the mask film and/or a part of the deposit by plasma of a processing gas which is a same kind as the processing gas used in the forming of the deposit and in which a flow rate ratio R2 is controlled to satisfy R2<R1. A taper angle of a pattern of the mask film is controlled to a required value by repeating the forming of the deposit and the removing of the part of the mask film and/or the part of the deposit a preset number of times.

### CROSS-REFERENCE TO RELATED APPLICATION

This application claims the benefit of Japanese Patent Application No. 2020-078482 filed on Apr. 27, 2020, the entire disclosure of which is incorporated herein by reference.

### TECHNICAL FIELD

The various aspects and embodiments described herein pertain generally to a processing method and a substrate processing apparatus.

### BACKGROUND

Patent Document 1, for example, proposes a technique including a process of depositing a deposit in a recess of a hole or line pattern and a process of removing a protruding portion of the hole or line pattern by etching to thereby reduce irregularity of the pattern.

Patent Document 2, for example, proposes a series of processes of providing a photoresist mask having a pattern formed thereon, putting a coating film on the photoresist mask, etching a target portion in an etching layer, and removing the mask.

Patent Document 1: U.S. Pat. No. 9,922,839

Patent Document 1: Japanese Patent Laid-open Publication No. 2010-516059

### SUMMARY

In one exemplary embodiment, a processing method of a substrate includes placing, on a placing table, the substrate having a mask film on an etching target film; forming a deposit on the mask film by plasma of a processing gas which includes a first gas and a second gas and in which a flow rate ratio R1 of the first gas to the second gas is controlled; and removing a part of the mask film and/or a part of the deposit by plasma of a processing gas which is a same kind as the processing gas used in the forming of the deposit and in which a flow rate ratio R2 of the first gas to the second gas is controlled to satisfy R2<R1. A taper angle of a side surface of a pattern of the mask film is controlled to a required value by repeating the forming of the deposit and the removing of the part of the mask film and/or the part of the deposit a preset number of times.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a longitudinal cross sectional view illustrating an example of a substrate processing apparatus according to an exemplary embodiment;

FIG. 2A to FIG. 2F are cross sectional views of films illustrating an example of processes of a substrate processing according to the exemplary embodiment;

FIG. 3 is a flowchart illustrating an example of a substrate processing method according to the exemplary embodiment;

FIG. 4A and FIG. 4B present example experimental results showing a cycle number and non-uniformity in patterns;

FIG. 5A is a diagram for describing definition of a taper angle of a pattern according to the exemplary embodiment;

FIG. 5B provides an example experimental result showing a taper angle of a pattern and non-uniformity of the pattern according to the exemplary embodiment;

FIG. 6A and FIG. 6B present example experimental results showing a time dependency of a taper angle in a depositing process and a removing process according to the exemplary embodiment;

FIG. 7 presents an example experimental result showing a gas dependency of CD non-uniformity in the depositing process according to the exemplary embodiment;

FIG. 8 presents an example experimental result showing a relationship between a variation of a gas flow rate and a taper angle according to the exemplary embodiment;

FIG. 9A to FIG. 9C present example experimental results showing a switchover of a deposition mode and a removing mode through a control over a gas flow rate according to the exemplary embodiment;

FIG. 10A to FIG. 10C are diagrams conceptually illustrating a processing time of the substrate processing method according to the exemplary embodiment;

FIG. 11A is a diagram for describing a processing method and adjustment of a taper angle according to the exemplary embodiment;

FIG. 11B is a diagram for describing the processing method and the adjustment of a taper angle according to the exemplary embodiment;

FIG. 11C is a diagram for describing the processing method and the adjustment of a taper angle according to the exemplary embodiment;

FIG. 11D is a diagram for describing the processing method and the adjustment of a taper angle according to the exemplary embodiment; and

FIG. 11E is a diagram for describing the processing method and the adjustment of a taper angle according to the exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

In the following description, exemplary embodiments of the present disclosure will be described with reference to the accompanying drawings. In the present specification and the drawings, substantially same parts will be assigned same reference numerals, and redundant description thereof may be omitted.

[Overall Configuration of Substrate Processing Apparatus]

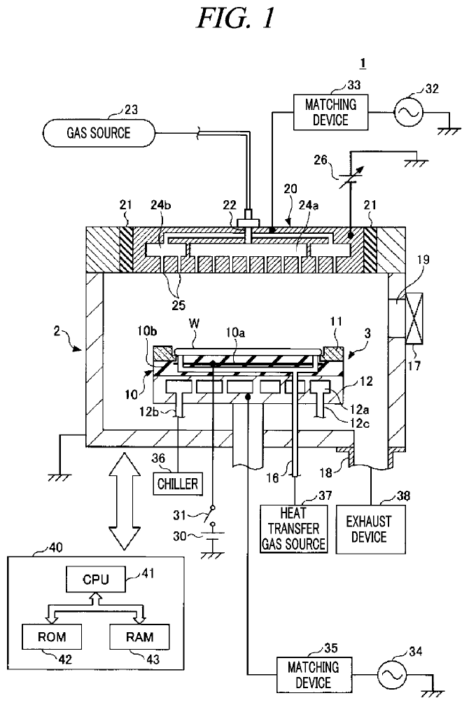

First, an example of a substrate processing apparatus 1 will be explained with reference to FIG. 1. The substrate processing apparatus 1 according to an exemplary embodiment is a capacitively coupled parallel plate type substrate processing apparatus, and has a substantially cylindrical processing vessel 2. An inside of the processing vessel 2 is configured as a processing chamber in which a plasma processing such as an etching processing or a film forming processing is performed by plasma. An inner surface of the processing vessel 2 is alumite-treated (anodically oxidized).

A stage 3 is provided within the processing vessel 2 to place thereon a wafer W as an example of a substrate. The stage 3 is made of, by way of non-limiting example, aluminum (Al), titanium (Ti), silicon carbide (SiC), or the like. The stage 3 is held on a bottom of the processing vessel 2 and serves as a lower electrode.

The stage 3 includes a base 12 and an electrostatic chuck 10 placed on the base 12. The electrostatic chuck 10 has a structure in which a chuck electrode 10a is embedded in an insulator 10b. The chuck electrode 10a is connected with a DC power supply 30, and the DC power supply 30 applies a DC voltage or stops the application of the DC voltage to the chuck electrode 10a as a switch 31 is opened or closed. If the DC voltage is applied to the chuck electrode 10a, the wafer W is electrostatically attracted to the electrostatic chuck 10 by a Coulomb force.

An edge ring 11 is of a circular ring shape, and is provided at a peripheral portion of the electrostatic chuck 10 to surround the wafer W. The edge ring 11 is made of, for example, silicon, and serves to expand a distribution range of the plasma formed above the wafer W to an outside of the wafer W to thereby improve uniformity of the plasma. The edge ring 11 is also called a focus ring.

A coolant path 12a is formed within the base 12. By way of example, a cooling medium (hereinafter, referred to as “coolant”) such as cooling water or brine is outputted from a chiller 36 and flown into a coolant path 12a from a coolant inlet line 12b. After flowing in the coolant path 12a, the coolant is then flown out from a coolant outlet line 12c and returned back into the chiller 36. Accordingly, heat of the stage 3 is removed, and the stage 3 is cooled. Further, the coolant is an example of a heat exchange medium for adjusting a temperature of the stage 3.

A heat transfer gas source 37 supplies a heat transfer gas such as a helium gas (He) into a gap between a front surface of the electrostatic chuck 10 and a rear surface of the wafer W through a heat transfer gas supply line 16. A temperature of the electrostatic chuck 10 is controlled by the coolant circulating in the coolant path 12a and the heat transfer gas supplied to the rear surface of the wafer W. As a result, the wafer W can be controlled to have a preset temperature.

A high frequency power supply 34 is connected to the stage 3 via a matching device 35, and applies a high frequency power LF for bias voltage generation having a preset frequency. The preset frequency may be, for example, 13.56 MHz. The matching device 35 serves to match a load impedance with an internal (or an output) impedance of the high frequency power supply 34.

A shower head 20 is disposed at a ceiling portion of the processing vessel 2 with a shield ring 21 therebetween to close a top opening of the processing vessel 2. The shield ring 21 covers a side surface of the shower head 20. The shower head 20 may be made of silicon. A high frequency power supply 32 is connected to the shower head 20 via a matching device 33 and applies a high frequency power HF for plasma formation having a first frequency higher than a second frequency. The first frequency may be, by way of example, 60 MHz. Further, the high frequency power HF may be applied to the stage 3.

A variable DC power supply 26 is connected to the shower head 20 and applies a negative DC voltage to the shower head 20. The shower head 20 also serves as a facing electrode (upper electrode) facing the stage 3 (lower electrode). The matching device 33 serves to match the load impedance with an internal (or an output) impedance of the high frequency power supply 32.

A gas source 23 supplies a gas for use in the plasma processing into a center diffusion space 24a and an edge diffusion space 24b via a gas inlet port 22. The gas diffused within the center diffusion space 24a and the edge diffusion space 24b are discharged toward the stage 3 through gas supply holes 25.

An exhaust port 18 is formed at a bottom surface of the processing vessel 2. An exhaust device 38 is connected to the exhaust port 18 and evacuates the processing vessel 2. Accordingly, an inside of the processing vessel 2 is maintained at a preset vacuum level. A gate valve 17 is provided at a sidewall of the processing vessel 2 and serves to open or close a transfer opening 19, thus allowing the wafer W to be carried into or out of the processing vessel 2 through the transfer opening 19.

A controller 40 controls an overall operation of the apparatus. The controller 40 includes a CPU 41, a ROM 42 and a RAM 43. The CPU 41 controls, according to a recipe stored in the ROM 42 or the RAM 43, the plasma processing such as etching or film formation by the plasma formed from a processing gas. In the recipe, control information of the apparatus upon processing conditions such as a processing time, a pressure (gas exhaust), high frequency powers or voltages, flow rates of various kinds of gases, temperatures within the processing vessel (a temperature of the upper electrode, a temperature of the sidewall of the processing vessel, a temperature of the wafer W, a temperature of the electrostatic chuck, etc.,), a coolant temperature, and so forth are set. Further, the recipe may be set at a preset position while being recorded on a computer-readable portable recording medium such as a hard disk, semiconductor memory, a CD-ROM, a DVD, etc., and read out.

When the plasma processing is performed, the controller 40 opens the gate valve 17, and allows the wafer W to be carried in through the transfer opening 19 and placed on the stage 3. The controller 40 applies a positive or negative DC voltage to the chuck electrode 10a, thus allowing the wafer W to be attracted to the electrostatic chuck 10.

The controller 40 supplies a required gas into the processing vessel 2 from the gas source 23. Further, the controller 40 applies a high frequency power HF and a negative DC voltage to the shower head 20 and applies a high frequency power LF to the stage 3. Accordingly, plasma is formed from the gas above the wafer W, and a plasma processing is performed on the wafer W.

Upon the completion of the plasma processing, the controller 40 applies a DC voltage having opposite polarity to the DC voltage applied to attract the wafer W to the chuck electrode 10a, and thus controls neutralization of electric charges of the wafer W. After the charge neutralization, the controller 40 separates the wafer W from the electrostatic chuck 10, and opens the gate valve 17, thus allowing the wafer W to be carried out from the processing vessel 2 through the transfer opening 19.

[Pattern Miniaturization]

With a progress of miniaturization of a semiconductor device formed on the wafer W, a wiring or contact resistance is increasing. For the reason, non-uniformity in the wiring or contact resistance causes non-uniformity in performance of the semiconductor device. Thus, it is important to reduce such non-uniformity in the manufacture of the semiconductor device.

In this regard, in a substrate processing method according to the exemplary embodiment to be described below, local critical dimension uniformity (hereinafter, simply referred to as “L-CDU”) of a contact hole pattern is improved. The L-CDU indicates non-uniformity of CD (critical dimension) sizes between adjacent contact holes. Further, as an example of an indicator which shows non-uniformity of a line pattern, LWR (line width roughness), LER (line edge roughness) or the like may be used.

[Processes of Substrate Processing]

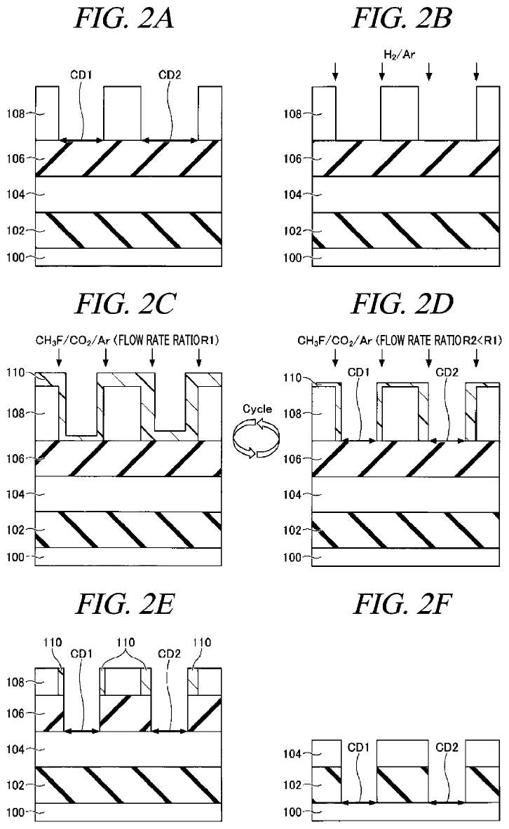

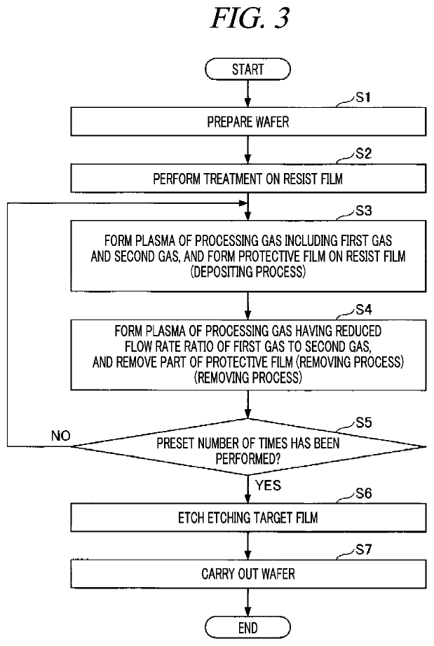

Referring to FIG. 2A to FIG. 3, processes of the substrate processing according to the exemplary embodiment will be explained. FIG. 2A to FIG. 2F are cross sectional views of a wafer W illustrating the processes of the substrate processing according to the exemplary embodiment. FIG. 3 is a flowchart illustrating an example of the substrate processing method according to the exemplary embodiment. Processings of individual processes shown in FIG. 3 are controlled by the controller 40.

(Initial State)

FIG. 2A is a cross sectional view illustrating stacked films on the wafer W in an initial state. The wafer W has a silicon oxide film 102, a SOC (Spin On Carbon) film 104, a SOG (Spin On Glass) film 106 and a resist film 108 which are stacked on a silicon substrate 100 in sequence.

The resist film 108 is an organic film provided with a contact hole pattern (hereinafter, also referred to as “mask pattern”), and serves as a patterned mask film. The SOG film 106, the SOC film 104 and the silicon oxide film 102 are examples of etching target films.

In a process 51 of FIG. 3, the controller 40 carries the wafer W having a film structure shown in FIG. 2A into the processing vessel 2, places the carried wafer W on the stage 3, and waits for a treatment process to be begun.

(Treatment Process)

Then, in a process S2, the controller 40 performs a treatment on the resist film 108 by plasma of a H₂ gas or plasma of HBr. FIG. 2B illustrates an example of supplying the H₂ gas and an Ar gas. Accordingly, a surface of the resist film 108 is treated to make the pattern shape better. This treatment process of the process S2 may be omitted.

(Cycle Stage: Depositing Process and Removing Process)

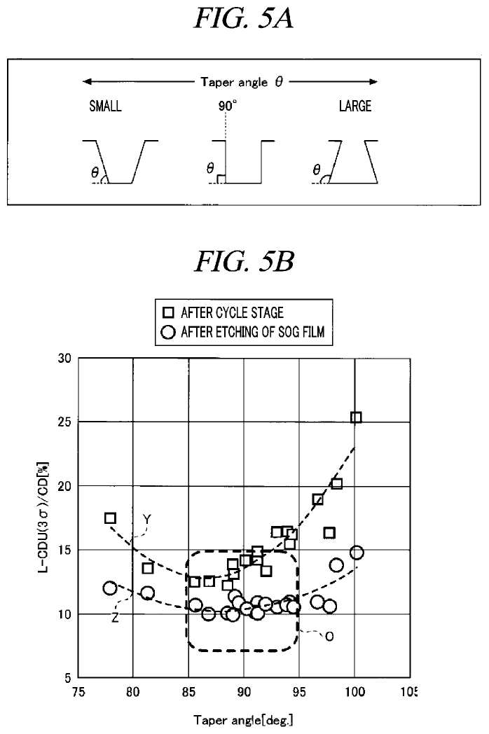

Referring back to FIG. 3, the controller 40 then controls a cycle stage in which a depositing process of a process S3 and a removing process of a process S4 are repeated to uniform CD sizes of the mask pattern of the resist film 108. To elaborate, in the depositing process of the process S3, the controller 40 forms plasma of a processing gas including a first gas and a second gas, and forms a deposit on a top surface, a side surface and a bottom surface (a top surface of the SOG film 106) of the resist film 108. Accordingly, a taper angle of a side surface of the mask pattern of the resist film 108 is increased (enlarged). As depicted in FIG. 5A, a taper angle (θ) refers to an angle of the resist film 108 formed by a tangent line which passes along the side surface of the mask pattern and a tangent line which passes along a bottom of the mask pattern. As depicted in FIG. 2C, a protective film 110 of the organic film is formed on the top surface, the side surface and the bottom surface of the resist film 108. In FIG. 2C, a CH₃F gas, a CO₂ gas and an Ar gas are supplied as an example of the processing gas. In the process S3, a flow rate ratio of the first gas to the second gas included in the processing gas is referred to as “R1.” That is, in the example of FIG. 2C, R1 is CH₃F/CO₂.

Subsequently, in the removing process of the process S4, the controller 40 forms plasma of a processing gas which is the same kind as the processing gas supplied in the depositing process. A flow rate ratio of the first gas to the second gas in the removing process, however, is smaller than the flow rate ratio R1 in the depositing process. The controller 40 removes a part of the protective film 110 formed in the depositing process through trimming by the formed plasma (removing process), and reduces the taper angle θ of the side surface of the mask pattern of the resist film 108. In FIG. 2D, a CH₃F gas, a CO₂ gas and an Ar gas are supplied as an example of the processing gas. In the process S4, the flow rate ratio of the first gas to the second gas included in the processing gas is referred to as “R2.” In the example of FIG. 2D, R2 is CH₃F/CO₂, and there is established a relationship of R2>R1.

The controller 40 controls the taper angle of the side surface of the mask pattern of the resist film 108 to a required value and removes non-uniformity of the CD sizes by performing the cycle stage at least one time. As a result, as depicted in FIG. 2D, the sizes of the CDs (for example, CD1 and CD2) of the mask pattern of the resist film 108 can be uniformed by the protective film 110 mainly left on the side surface of the resist film 108. Further, the depositing process corresponds to a process in which a deposit is formed on the mask film by plasma formed from the processing gas which includes the first gas and the second gas and in which the flow rate ratio of the first gas to the second gas is R1. The removing process corresponds to a process in which a part of the mask film and/or a part of the deposit is removed by plasma formed from the processing gas which is the same kind as the processing gas used in the depositing process and in which the flow rate ratio of the first gas to the second gas is R2 (R2<R1). Further, either the depositing process or the removing process may be performed first.

Subsequently, in a process S5 of FIG. 3, the controller 40 makes a determination upon whether the depositing process and the removing process (cycle stage) have been performed a preset number of times (hereinafter, also referred to as “cycle number”).

If it is determined that the cycle stage has not been performed as many as the preset cycle number, the controller 40 then returns back to the process S3 and repeats the processes S3 to S5. Accordingly, the taper angle of the side surface of the mask pattern of the resist film 108 is controlled to the required value, and the CD sizes of the mask pattern are uniformed. Further, the cycle number is previously set to be equal to or larger than one.

(Etching Process)

If it is determined in the process S5 that the cycle stage has been performed as many as the preset cycle number, the controller 40 etches, in a process S6, the SOG film 106 which is one of the etching target films. As a result, as depicted in FIG. 2E, the SOG film 106 is etched to have the mask pattern of the resist film 108. Then, the controller 40 etches the other etching target films, that is, the SOC film 104 and the silicon oxide film 102 in this sequence. As a result, contact holes having the same CD size (for example, CD1, CD2) are formed in the silicon oxide film 102, as depicted in FIG. 2F. Thereafter, in a process S7 of FIG. 3, the controller 40 takes out the wafer W from the processing vessel 2, and ends the present processing.

Further, the wafer W carried to the outside of the processing vessel 2 is transferred into an ashing apparatus or a wet cleaning apparatus. The ashing apparatus or the wet cleaning apparatus removes the SOC film 104 on the silicon oxide film 102 and residues on the wafer W. The removing of the SOC film 104 and the residues, however, may not be limited thereto, and may be performed by ashing within the same processing vessel as the processing vessel 2 in which the cycle stage has been performed after the processing of the process S6 and before the processing of the process S7, for example.

[Processing Conditions]

Now, processing conditions for the individual processes in the above-described substrate processing method will be explained.

(Treatment Process)

A processing condition for the treatment process (process S2) of FIG. 3 is as follows.

Gas Kinds: H₂ Gas and Ar Gas

In the treatment process, however, the gas kinds are not limited to the aforementioned gases. For example, a HBr gas and an Ar gas may be supplied.

(Depositing Process)

A processing condition for the depositing process (process S3) is specified as follows.

Gas Kinds: CH₃F Gas, CO₂ Gas and Ar Gas

The CH₃F gas is an example of the first gas included in the processing gas supplied in the depositing process. The first gas may include a gas which generates a precursor capable of depositing a deposit on the etching target film by the plasma. The first gas is not limited to the CH₃F gas, and may be a fluorocarbon (CF) gas such as a C₄F₈ gas, a C₄F₆ gas, a C₅F₈ gas, or the like. Alternatively, the first gas may be a hydrocarbon (CH) gas such as a CH₄ gas or a C₂H₆ gas, or a hydrofluorocarbon (CHF) gas such as a CH₂F₂ or CHF₃. Still alternatively, a gas including at least one of the fluorocarbon gas, the hydrocarbon gas and the hydrofluorocarbon gas may be used as the first gas.

The CO₂ gas is an example of the second gas included in the processing gas supplied in the depositing process. The second gas may include a gas which generates a precursor capable of removing the deposit formed on the etching target film by the plasma. The second gas is not limited to the CO₂ gas and may include an oxygen-containing gas at least. The oxygen-containing gas may include at least one of an oxygen (O₂) gas, a carbon dioxide (CO₂) gas, a carbon monoxide (CO) gas and an ozone (O₃) gas.

The Ar gas is an example of an inert gas included in the processing gas supplied in the depositing process. An N2 gas or any of other inert gases may be used in lieu of the Ar gas.

(Removing Process)

A processing condition for the removing process (process S4) is specified as follows.

Gas Kinds: CH₃F Gas, CO₂ Gas and Ar Gas

That is, the processing gas supplied in the removing process is the same kind as the processing gas supplied in the depositing process. However, the flow rate ratio R1 of the first gas to the second gas in the depositing process and the flow rate ratio R2 of the first gas to the second gas in the removing process are controlled to satisfy the relationship of R2<R1.

The controller 40 changes a flow rate of at least one of the first gas and the second gas when the depositing process is switched to the removing process, and when the removing process is switched to the depositing process. Further, when the depositing process is switched to the removing process, and vice versa, the plasma may be maintained.

(Etching Process)

A processing condition for the etching process (process S6) is specified as follows.

Gas Kinds: CH₃F Gas and CF₄ Gas

In the etching process, however, the gas kinds are not limited to the aforementioned gases.

[Cycle Number]

In the depositing process, the deposit is formed on the side surfaces of the contact holes as well as on the top surfaces and the bottom surfaces thereof. At this time, the deposit adheres to the side surface of the wide hole more than the side surface of the narrow hole (loading effect). In the present exemplary embodiment, this loading effect of the deposit is used.

In the removing process, the deposits attached to the side surfaces of the contact holes in the depositing process are uniformly removed. By repeating this depositing process and the removing process, the CD sizes of the contact holes can be uniformed, so that the L-CDU can be improved.

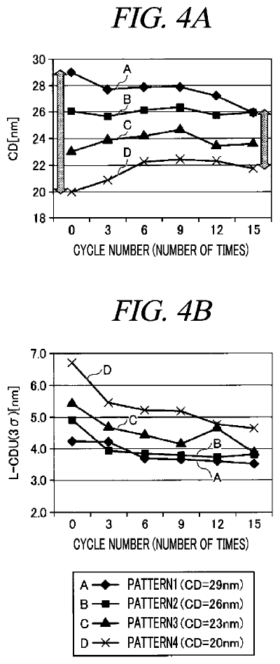

Graphs of FIG. 4A and FIG. 4B show examples of experimental results upon a cycle number and non-uniformity of mask patterns when the depositing process and the removing process are repeated. A horizontal axis of the graph of FIG. 4A represents a cycle number (number of times), and a vertical axis thereof shows experimental results of CD values (nm) of mask patterns 1 to 4 according to the cycle number. The mask patterns 1 to 4 have different initial CD values and are respectively indicated by lines A to D.

A horizontal axis of FIG. 4B represents a cycle number, and a vertical axis thereof show experimental results of L-CDU (3σ) of the mask patterns indicated by the lines A to D according to the cycle number. Here, L-CDU (3σ) stands for a value of 3σ (σ: standard deviation).

In FIG. 4A and FIG. 4B, a maximum CD difference between the mask pattern 1 (CD=29 nm) of the line A, the mask pattern 2 (CD=26 nm) of the line B, the mask pattern 3 (CD=23 nm) of the line C and the mask pattern 4 (CD=20 nm) of the line Din the initial state is found to be 9 nm (=29 nm−20 nm).

If the cycle number increases as the cycle stage (the depositing process and the removing process) is repeated, the maximum CD difference decreases, as depicted in FIG. 4A. When the cycle number reaches 15, the maximum CD difference is found to be 4 nm (=26 nm−22 nm). Likewise, if the cycle number increases, the value of L-CDU (3σ) decreases in each of the mask patterns 1 to 4, as depicted in FIG. 4B. When the cycle number reaches 15, the L-CDU (3σ) is found to be improved the most, and non-uniformity in the CD sizes between the neighboring contact holes is found be reduced. Further, though the L-CDU is represent by the value of “3σ” in the present exemplary embodiment, the L-CDU is not limited thereto, and σ or 2σ may be used instead.

[Taper Angle]

As shown in FIG. 5A, a taper angle θ when the side surface of the mask pattern is vertical is assumed to be 90°. When the mask pattern has a reversed taper shape (that is, when a recess (opening) has a taper shape), the taper angle is larger than 90°. When the mask pattern has a taper shape (that is, when the recess (opening) has a reversed taper shape), the taper angle is smaller than 90°.

A horizontal axis of a graph of FIG. 5B represents a taper angle θ of the mask pattern, and a vertical axis thereof presents an example experimental result showing non-uniformity of the mask pattern represented by L-CDU (3σ)/CD. The L-CDU (3σ)/CD on the vertical axis of FIG. 5B is L-CDU (3σ) per a unit length. The L-CDU is a value of 3σ, but not limited thereto.

Here, a line Y represents L-CDU (3σ)/CD for the taper angle θ after the cycle stage. A line Z represents L-CDU (3σ)/CD for the taper angle θ after the etching of the SOG film 106. In any of these two cases, by adjusting the taper angle θ of the mask pattern within a range from 85° to 95°, non-uniformity of the mask pattern and the SOG film 106 can be reduced, as shown in a dashed-lined circle O.

That is, it is found out that, to reduce the L-CDU (3σ)/CD, it is desirable to adjust the taper angle θ of the mask pattern after the cycle stage to be in the range from 85° to 95°.

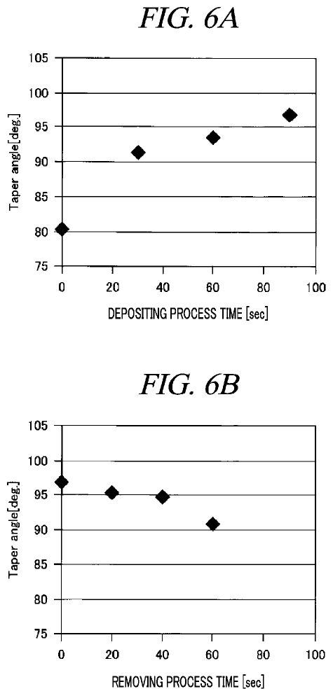

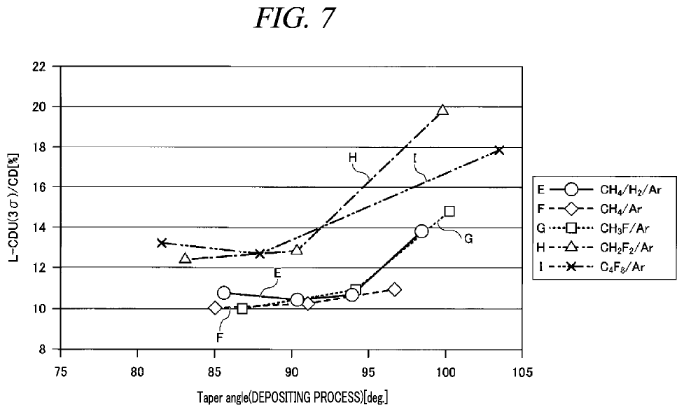

FIG. 6A and FIG. 6B present example experimental results showing time dependency of the taper angle θ in the depositing process and the removing process according to the exemplary embodiment. Processing conditions for the depositing process and the removing processes are the same as specified above. In the experimental result of FIG. 6A, it is found out that: a deposit adheres more easily to an upper portion of the mask pattern in the depositing process; and the taper angle θ increases with an increase of a processing time of the depositing process and becomes larger than 90° so the mask pattern ends up with having a reversed taper shape.

Further, in the experimental result of FIG. 6B, it is found out that: the protective film 110 formed on the top portion of the mask pattern is removed more easily in the removing process; and the taper angle θ decreases with an increase of a processing time of the removing process and becomes smaller than 90° so the mask pattern ends up with having a taper shape.

As can be seen from the above, the taper angle θ can be increased in the depositing process by attaching the deposit to the side surface of the contact hole, whereas the taper angle θ can be reduced in the removing process by removing a part of the deposit on the side surface of the contact hole. Accordingly, by repeating the depositing process and the removing process, the taper angle of the mask pattern can be controlled. Further, by controlling the cycle number or each processing time when the depositing process and the removing process are repeated, a depositing process time and a removing process time can be controlled, and, thus, by adjusting the taper angle to be in the range from 85° to 95°, the L-CDU can be improved.

That is, by repeating the depositing process and the removing process, the controller 40 is capable of controlling a processing time of the cycle stage and adjusting the mask shape so that the taper angle after the cycle stage becomes 85° to 95°. As a consequence, the L-CDU can be improved. In this way, by performing the processing of removing the non-uniformity of the CD sizes of the resist film 108, non-uniformity of CD sizes when etching the SOG film 106 can be suppressed. Furthermore, non-uniformity of CD sizes when etching the SOC film 104 and the silicon oxide film 102 in sequence by using the SOG film 106 as a mask can also be suppressed. Thus, by allowing the silicon oxide film 102 to have a vertical etching shape and by removing CD non-uniformity of the etching shape, non-uniformity in wiring and contact resistance can be reduced, so that a device performance can be improved.

[Gas Dependency]

Now, gas dependency of CD non-uniformity in the depositing process according to the exemplary embodiment will be explained with reference to FIG. 7. FIG. 7 provides example experimental results showing the gas dependency of the CD non-uniformity in the depositing process according to the exemplary embodiment.

A line E of a graph of FIG. 7 represents L-CDU (3σ)/CD for a taper angle θ after a depositing process in which a CH₄ gas, a H₂ gas and an Ar gas are used. A line F indicates L-CDU (3σ)/CD for the taper angle θ after a depositing process in which a CH₄ gas and an Ar gas are used. A line G represents L-CDU (3σ)/CD for the taper angle θ after a depositing process in which a CH₃F gas and an Ar gas are used. A line H represents L-CDU (3σ)/CD for the taper angle θ after a depositing process in which a CH₂F₂ gas and an Ar gas are used. A line I represents L-CDU (3σ)/CD for the taper angle θ after a depositing process in which a C₄F₈ gas and an Ar gas are used.

According to this experiment, it is found out that the L-CDU (3σ)/CD can be reduced by adjusting the taper angle θ to be in the range from 85° to 95° regardless of which of the gases indicated by the lines E to I is used. That is, in the depositing process, the taper angle θ is adjusted to 85° to 95° by plasma of the first gas including at least one of the hydrocarbon (CH) gas, the hydrofluorocarbon (CHF) gas and the fluorocarbon (CF) gas. Accordingly, it is found out that the L-CDU can be improved.

Particularly, the CH₄ gas, the H₂ gas and the Ar gas indicated by the line E, the CH₄ gas and the Ar gas indicated by the line F, and the CH₃F gas and the Ar gas indicated by the line G are found to be capable of reducing the L-CDU (3σ)/CD more than the CH₂F₂ gas and the Ar gas indicated by the line H and the C₄F₈ gas and the Ar gas indicated by the line I.

[Gas Flow Rates]

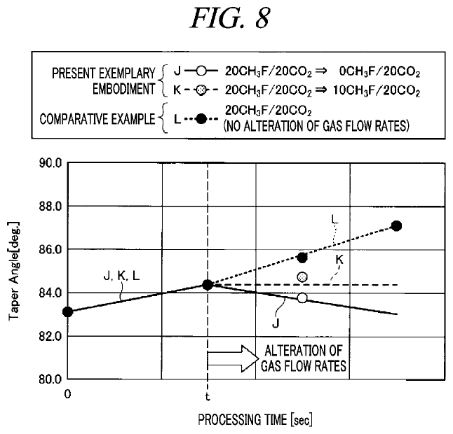

Now, a relationship between an alteration of gas flow rates and a taper angle θ will be explained with reference to FIG. 8. FIG. 8 provides experimental results showing a relationship between an alteration of gas flow rates and a taper angle according to the exemplary embodiment. A horizontal axis of FIG. 8 represents a processing time when the gas flow rates are changed at a time t, and a vertical axis indicates a taper angle θ.

In the present experiment, a CH₃F gas, a CO₂ gas and an Ar gas are used. A line J of FIG. 8 shows an experimental example of the processing method according to the present exemplary embodiment. In this experimental example, flow rates of the gases are controlled so that a flow rate ratio R1 (=CH₃F/CO₂) of the gases becomes 20/20 in a depositing process, and the flow rates of the gases are changed so that a flow rate ratio R2 at the time t becomes 0/20. A processing time before the time t is the depositing process, and a processing time after the alteration of the flow rates of the gases at the time t is a removing process.

A line K of FIG. 8 shows an experimental example of the processing method according to the present exemplary embodiment. Here, flow rates of the gases are controlled so that a flow rate ratio R1 (=CH₃F/CO₂) of the gases becomes 20/20 in a depositing process, and the flow rates of the gases are changed so that a flow rate ratio R2 at the time t becomes 10/20. A processing time before the time t is the depositing process, and a processing time after the alteration of the flow rates of the gases at the time t is a removing process.

A line L of FIG. 8 shows a comparative example, and indicates a case where flow rates of the gases are not changed, and the flow rates of the respective gases are controlled so that a flow rate ratio R1 (=CH₃F/CO₂) becomes 20/20. As a result, in any of the cases indicated by the lines J and K according to the present exemplary embodiment, after the alteration of the flow rates of the gases at the time t, the taper angle is reduced as compared to the case of the line L indicating the comparative example.

In comparison of the lines J to L, the flow rate ratio of the CH₃F gas to the CO₂ gas at the processing time after the time t is found to be the largest in the comparative example indicated by the line L, the smallest in the present exemplary embodiment indicated by the line J, and in the middle therebetween in the present exemplary embodiment indicated by the line K. The CH₃F gas has a function of depositing the protective film 110 mainly, and the CO₂ gas has a function of removing the protective film 110 mainly. For the reason, in the comparative example indicated by the line L in which the flow rate ratio of the CH₃F gas to the CO₂ gas is the largest, a deposition amount of the protective film 110 increases with an increase of the processing time, resulting in an increase of the taper angle θ. In the present exemplary embodiment indicated by the line J in which the flow rate ratio of the CH₃F gas to the CO₂ gas is the smallest, the protective film 110 is removed with an increase of the processing time and the taper angle θ is reduced after the flow rates of the gases are changed at the time t. In the exemplary embodiment indicated by the line K where the flow rate ratio of the CH₃F gas to the CO₂ gas is controlled to be in the middle between the lines J and L, an increment/decrement of the deposition amount of the protective film 110 after the alteration of the flow rates of the gases at the time t is controlled to be in the middle between the lines J and L.

As can be seen from the above, by controlling the flow rate ratio R1 of the first gas to the second gas in the depositing process and/or by controlling the flow rate ratio R2 of the first gas to the second gas in the removing process, the taper angle θ of the reset film 108 can be adjusted, and, accordingly, the L-CDU can be improved.

Further, in the control of the flow rates of the gases, if the flow rate ratio R2 of the first gas to the second gas in the removing process becomes smaller than the flow rate ratio R1 of the first gas to the second gas in the depositing process, the flow rate ratio R2 can be zero.

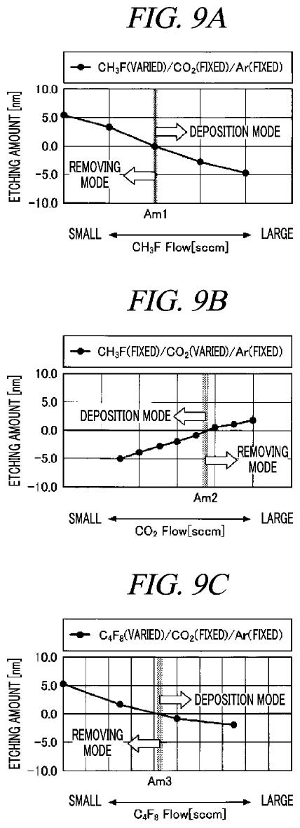

Now, adjustment of gas flow rates and a switchover between a deposition mode and a removing mode will be explained with reference to FIG. 9A to FIG. 9C. FIG. 9A to FIG. 9C provide example experimental results showing adjustment of gas flow rates and a switchover between the deposition mode and the removing mode according to the exemplary embodiment. A horizontal axis of a graph of each of FIG. 9A to FIG. 9C represents a flow rate of a gas to be adjusted, and a vertical axis indicates an etching amount of the protective film 110 on the resist film 108. In the deposition mode, the protective film 110 deposited on the resist film 108 is thickened, whereas, in the removing mode, the protective film 110 is thinned.

The vertical axes of the graphs of FIG. 9A and FIG. 9B represent an etching amount when etching is performed by plasma of a processing gas including a CH₃F gas, a CO₂ gas and an Ar gas. The graph of FIG. 9C shows an etching amount when etching is performed by plasma of a processing gas including a C₄F₈ gas, a CO₂ gas and an Ar gas. In all the experiments of FIG. 9A to FIG. 9C, the Ar gas is controlled to be fixed at a predetermined flow rate.

On the graph of FIG. 9A, a flow rate of the CO₂ gas is fixed, whereas a flow rate of the CH₃F is varied. The horizontal axis of the graph of FIG. 9A indicates the flow rate of the CH₃F gas, and the flow rate of the CH₃F gas increases as it goes to the right.

According to this experimental result, a flow rate ratio of the CH₃F gas to the CO₂ gas increases with an increase of the flow rate of the CH₃F gas, bringing up the deposition mode in which the protective film 110 is deposited. That is, by adjusting the flow rate of the CH₃F gas to be larger than a flow rate Am1 at which the etching amount becomes zero, the deposition mode can be brought up, and by adjusting the flow rate of the CH₃F gas to be smaller than the flow rate Am1, the deposition mode can be switched to the removing mode. Thus, it is found out that the taper angle θ of the resist film 108 can be adjusted by controlling the flow rate of the CH₃F gas to the flow rate of the CO₂ gas.

On the graph of FIG. 9B, a flow rate of the CH₃F gas is fixed, whereas a flow rate of the CO₂ gas is varied. The horizontal axis of the graph of FIG. 9B indicates the flow rate of the CO₂ gas, and the flow rate of the CO₂ gas increases as it goes to the right.

According to this experimental result, a flow rate ratio of the CH₃F gas to the CO₂ gas decreases with an increase of the flow rate of the CO₂ gas, bringing up the removing mode in which the protective film is removed. That is, by adjusting the flow rate of the CO₂ gas to be larger than a flow rate Am2 at which the etching amount becomes zero, the removing mode can be brought up, and by adjusting the flow rate of the CO₂ gas to be smaller than the flow rate Am2, the removing mode can be switched to the deposition mode. Thus, it is found out that the taper angle of the resist film 108 can be adjusted by controlling the flow rate of the CO₂ gas to the flow rate of the CH₃F gas.

Further, on the graph of FIG. 9C, a flow rate of the CO₂ gas is fixed, and a flow rate of the C₄F₈ gas is varied. A horizontal axis of the graph of FIG. 9C represents the flow rate of the C₄F₈ gas, and the flow rate of the C₄F₈ gas increases as it goes to the right.

According to this experimental result, a flow rate ratio of the C₄F₈ gas to the CO₂ gas increases with an increase of the flow rate of the C₄F₈ gas, bringing up the deposition mode in which the protective film is deposited. That is, by adjusting the flow rate of the C₄F₈ gas to be larger than a flow rate Am3 at which the etching amount becomes zero, the deposition mode can be brought up, and by adjusting the flow rate of the C₄F₈ gas to be smaller than the flow rate Am3, the deposition mode can be switched to the removing mode.

From the above-described experiments, by increasing the flow rate of the depositive gas such as the CH₃F gas or the C₄F₈ gas, the deposition mode can be brought up, and by increasing the flow rate of the removing gas such as the CO₂ gas, the removing mode can be brought up. Thus, by adjusting at least one of the depositive gas or the removing gas, the deposition mode and the removing mode can be switched.

[Throughput]

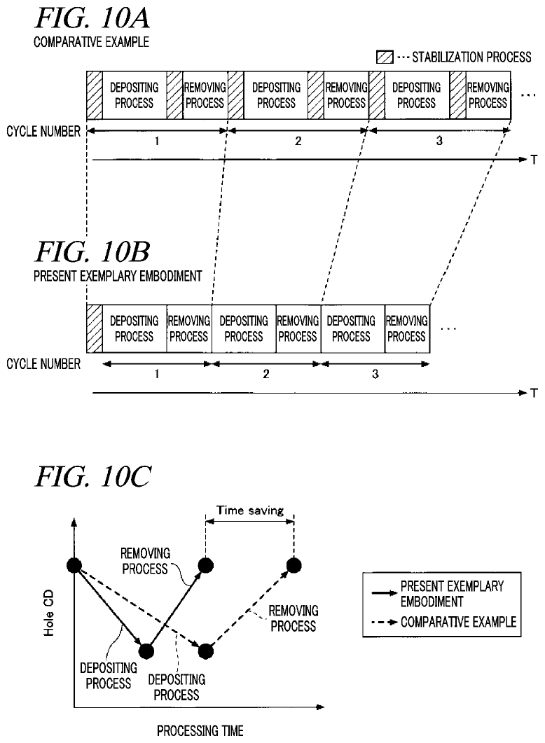

Now, improvement of a throughput in the substrate processing method according to the exemplary embodiment will be discussed with reference to FIG. 10A to FIG. 10C. FIG. 10A to FIG. 10C are conceptual diagrams showing a comparison of a processing time of the substrate processing method according to the present exemplary embodiment and a processing time of the substrate processing method according to a comparative example. FIG. 10A is a diagram showing an example of a substrate processing method according to the comparative example. FIG. 10B is a diagram illustrating an example of the substrate processing method according to the present exemplary embodiment. As depicted in FIG. 10A, in the substrate processing method according to the comparative example, a stabilization process is required between a depositing process and a removing process. In contrast, as shown in FIG. 10B, a stabilization process is not required between the depositing process and the removing process in the substrate processing method according to the present exemplary embodiment.

In the comparative example shown in FIG. 10A, the kind of at least one of a first gas or a second gas is different between processing gases supplied in the depositing process and the removing process, and a gas within the processing vessel 2 needs to be changed to a different kind of gas when the depositing process and the removing process are switched. When the gas within the processing vessel 2 is changed to the different kind of gas, the gas of the following process needs to be supplied while the gas of the preceding process is exhausted, and a stabilization process as a process for allowing the gas within the processing vessel 2 to be changed sufficiently is required. This stabilization process is necessary when the depositing process is switched to the removing process, and vice versa.

In contrast, in processing conditions for the depositing process and the removing process according to the present exemplary embodiment shown in FIG. 10B, the kind of the processing gas is not changed between the depositing process and the removing process as stated above, and only a flow rate ratio of the first gas to the second gas in the processing gas is changed. For the reason, a stabilization process for changing the gas for the switchover between the depositing process and the removing process is not required. As a result, in the substrate processing method according to the present exemplary embodiment, a total processing time can be shortened by as much as a time of the stabilization process as the cycle number increases, as compared to the comparative example. Therefore, a throughput can be improved.

A horizontal axis of FIG. 10C represents a processing time in the comparative example of FIG. 10A and the present exemplary embodiment of FIG. 10B, and a vertical axis indicates a CD (see FIG. 2E) at a bottom of a hole formed in an etching target film. In the present exemplary embodiment, the stabilization process is not required. Therefore, the CD value of the bottom of the hole can be controlled to be reduced (depositing process) or increased (removing process) with a processing time shorter than that in the comparative example.

[Adjustment of Taper Angle]

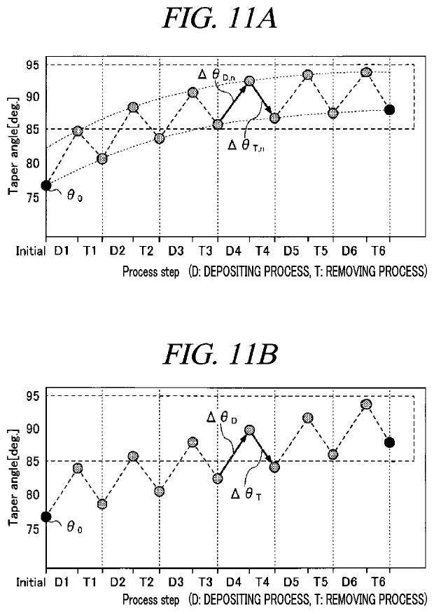

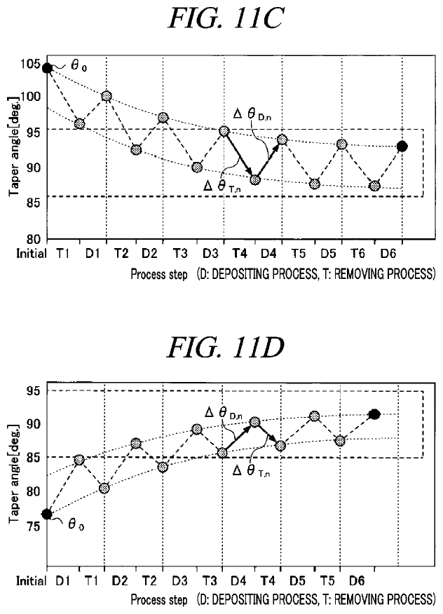

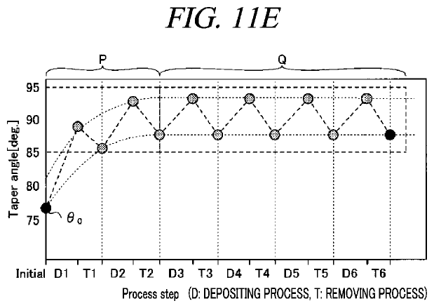

Now, adjustment of a taper angle in a cycle stage of a substrate processing will be explained with reference to FIG. 11A to FIG. 11E. FIG. 11A to FIG. 11E are diagrams for describing adjustment of a taper angle in the substrate processing method according to the exemplary embodiment.

As shown in FIG. 11A to FIG. 11E, θ₀ represents a taper angle of a side surface of the resist film 108 in an initial state, and the depositing process and the removing process are repeated a preset number of times N (N=cycle number, N is an integer equal to or larger than 1). If an increment of the taper angle in an n^{th} (n≤N) depositing process is referred to as Δθ_{D, n} and a decrement of the taper angle in an n^{th} removing process is referred to as Δθ_{T, n}, the following expression (1) is satisfied. Further, the controller 40 controls processing conditions (processing times, gas flow rates, etc.,) for the depositing process and the removing process to satisfy the following expression (1).

$$\begin{matrix}[ Expression 1 ] & \\ 85 ° ≦ {\sum }_{n = 1}^{N} ( Δ {θ}_{D , n} - Δ {θ}_{T , n} ) + {θ}_{0} ≦ 95 ° & ( 1 )\end{matrix}$$

In FIG. 11A to FIG. 11E, D1, D2, D3 . . . represent a depositing process D, and T1, T2, T3 . . . represent a removing process T. In the depositing process D, the taper angle of the side surface of the resist film 108 increases, whereas in the removing process T, the taper angle of the side surface of the resist film 108 decreases.

The expression (1) shows a conditional expression which allows the taper angle to be in the range from 85° to 95° when a variation of the taper angle differs each time, as shown in FIG. 11A.

Expression (2) shows a conditional expression which allows the taper angle to be in the range from 85° to 95° when the variation of the taper angle is same each time, as shown in FIG. 11B.

[Expression 2]

85°≤(Δθ_{D}−Δθ_{T})×N+θ₀≤95° (2)

The processing condition to be adjusted may be at least one of processing times of the depositing process and the removing process, a flow rate ratio R1 of the first gas to the second gas controlled in the depositing process, or a flow rate ratio R2 of the first gas to the second gas controlled in the removing process. By way of example, the previously obtained data indicating the relationship between the processing times (the depositing process time and the removing process time) and the taper angle θ shown in FIG. 6A and FIG. 6B may be stored in the ROM 42 or the RAM 43, and the CPU 41 may control the processes based on the stored data.

Further, as for the flow rate ratios R1 and R2 of the first gas to the second gas, the previously obtained data indicating the relationship between the flow rate ratios, the taper angle θ and the processing time shown in FIG. 8 may be stored in the ROM 42 or the like, and the CPU 41 may control the processes based on the stored data. The processing conditions may be identical except the flow rate ratio R1 of the first gas to the second gas in the depositing process and the flow rate ratio R2 of the first gas to the second gas in the removing process.

Data indicating a relationship between the taper angle θ and processing parameters such as a pressure in the depositing process, a temperature in the depositing process, a pressure in the removing process and a temperature in the removing process may be previously stored in the ROM 42 or the RAM 43, and the CPU 41 may adjust the processes based on this data.

Further, the repetition number of the depositing process and the repetition number of the removing process may be same or different. Further, if the repetition number of the depositing process and the removing process is equal to or larger than 2, processing conditions for an n^{th} depositing process and processing conditions for an (n+1)^{th} depositing process may be same or different.

Moreover, if the repetition number of the depositing process and the removing process is equal to or larger than 2, processing conditions for an n^{th} removing process and processing conditions for an (n+1)^{th} removing process may be same or different in any case where the processing conditions for the n^{th} depositing process and the processing conditions for the (n+1)^{th} depositing process are same or different.

In the above-described processing method, the removing process is performed after the depositing process is performed first, and the depositing process and the removing process are repeated. However, the exemplary embodiment is not limited thereto. As shown in FIG. 11C, the depositing process may be performed after the removing process is first performed. Particularly, when the initial taper angle θ is larger than 90°, the processing may start from the removing process of reducing the taper angle θ, and, thus, it is possible to obtain a required angle faster.

Expression (3) presents a conditional expression allowing the taper angle to fall within the range from 85° to 95° according to a variation of the taper angle, as shown in FIG. 11C.

$$\begin{matrix}[ Expression 3 ] & \\ 85 ° ≦ {\sum }_{n = 1}^{N} ( - Δ {θ}_{T , n} + Δ {θ}_{D , n} ) + {θ}_{0} ≦ 95 ° & ( 3 )\end{matrix}$$

Further, when the depositing process and the removing process are repeated, the repetition number of each process is set to be same in the above-described processing method. However, the exemplary embodiment is not limited thereto. By way of example, when the removing process is performed after the depositing process is first performed as shown in FIG. 11D, the depositing process may be performed N times, and the removing process may be performed N−1 times.

Expression (4) presents a conditional expression allowing the taper angle to be within the range from 85° to 95° according to a variation of the taper angle, as shown in FIG. 11D.

$$\begin{matrix}[ Expression 4 ] & \\ 85 ° ≦ {\sum }_{n = 1}^{N} ( Δ {θ}_{D , n} - Δ {θ}_{T , n} ) + {θ}_{0} ≦ 95 ° Here , Δ {θ}_{T , N} = 0 & ( 4 )\end{matrix}$$

Further, when the depositing process is performed after the removing process is first performed, the removing process may be performed N times, and the depositing process may be performed N−1 times.

While the n^{th} depositing process (removing process) is being performed, the substrate W may be processed under the same processing conditions, or the period during which the n^{th} depositing process is performed may be divided into multiple stages, and parameters such as the gas flow rates may be changed. Further, the period during which the n^{th} removing process is performed may be divided into multiple stages, and parameters such as the gas flow rates may be changed.

Further, the controller 40 may control the cycle stage including the depositing process and the removing process in two steps shown in FIG. 11E. In this case, in a first-step cycle stage P, the controller 40 performs a control so that the side surface of the resist film 108 has a substantially vertical shape. By way of example, in the example of FIG. 11E, the controller 40 performs the control such that the taper angle falls within the range from 85° to 95°. Then, in a second-step cycle stage Q, the controller 40 performs a control to satisfy the expression (5) while allowing the side surface of the resist film 108 to have a substantially vertical shape. In the example of FIG. 11E, the controller 40 performs a control to satisfy the expression (5) while allowing the taper angle to fall within the range from 85° to 95°.

[Expression 5]

Δθ_{D}−Δθ_{T}≅0° (5)

Accordingly, in the first-step cycle stage P, the side surface of the resist film 108 is adjusted to be of the substantially vertical shape, and in the second-step cycle stage Q irregularity of a pattern surface can be reduced while the vertical shape of the side surface of the resist film 108 is maintained, so that the pattern surface can be made smooth. That is, in the first-step cycle stage P, the taper angle can be controlled. Then, in the depositing process of the second-step cycle stage Q, a deposit is deposited in a recess of the pattern surface, and in the removing process of the second-step cycle stage Q, etching is performed from a protruding portion of the pattern surface. Accordingly, it is possible to reduce the irregularity of the pattern surface while maintaining the substantially vertical shape of the taper angle.

As stated above, the substrate processing method according to the present exemplary embodiment includes: (a) a process of placing, on a placing table, a substrate having a mask film on an etching target film; (b) a process of forming a deposit on the mask film by plasma of a processing gas including a first gas and a second gas and having a controlled flow rate ratio R1 of the first gas to the second gas; and (c) removing a part of the mask film and/or a part of the deposit by plasma of a processing gas which is the same kind as the processing gas in the process (b) and having a controlled flow rate ratio R2 of the first gas to the second gas (R2<R1). A taper angle of a side surface of a pattern of the mask film is controlled to a required value by repeating the process (b) and the process (c) a preset number of times. Accordingly, non-uniformity of the mask pattern can be suppressed, and a throughput can be improved.

It should be noted that the processing method and the substrate processing apparatus according to the above-described exemplary embodiments are illustrative in all aspects and are not anyway limiting. The above-described exemplary embodiments can be modified and improved in various ways without departing from the scope and the spirit of claims. Unless contradictory, the disclosures in the various exemplary embodiments can be combined appropriately, and various other configurations may be adopted.

The substrate processing apparatus of the present disclosure may be applicable to any of various types such as capacitively coupled plasma (CCP), inductively coupled plasma (ICP), radial line slot antenna (RLSA), electron cyclotron resonance plasma (ECR), and helicon wave plasma (HWP).

The substrate W is not limited to the wafer, and may be any of various kinds of substrates for use in FPD (Flat Panel Display), a print substrate, or the like.

According to the exemplary embodiment, it is possible to improve a throughput while suppressing non-uniformity in a mask pattern.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A processing method of a substrate, comprising:
placing, on a placing table, the substrate having a mask film on an etching target film;
forming a deposit on the mask film by plasma of a processing gas which includes a first gas and a second gas and in which a flow rate ratio R1 of the first gas to the second gas is controlled; and
removing a part of the mask film and/or a part of the deposit by plasma of a processing gas which is a same kind as the processing gas used in the forming of the deposit and in which a flow rate ratio R2 of the first gas to the second gas is controlled to satisfy R2<R1,
wherein a taper angle of a side surface of a pattern of the mask film is controlled to a required value by repeating the forming of the deposit and the removing of the part of the mask film and/or the part of the deposit a preset number of times.

2. The processing method of claim 1,
wherein the plasma is maintained when the forming of the deposit is switched to the removing of the part of the mask film and/or the part of the deposit and when the removing of the part of the mask film and/or the part of the deposit is switched to the forming of the deposit.

3. The processing method of claim 1,
wherein in the forming of the deposit, the taper angle is increased by forming the deposit, and
in the removing of the part of the mask film and/or the part of the deposit, the taper angle is reduced by removing the part of the deposit.

4. The processing method of claim 3,
wherein when the taper angle of the mask film in an initial state is θ₀; the forming of the deposit and the removing of the part of the mask film and/or the part of the deposit are repeated a preset number of times N (N is an integer equal to or larger than 1); an increment of the taper angle in an n^{th} (n≤N) forming of the deposit is Δθ_{D, n}; and a decrement of the taper angle in an n^{th} removing of the part of the mask film and/or the part of the deposit is Δθ_{T, n}, a following expression (1) is satisfied:
$$\begin{matrix}[ Expression 1 ] & \\ 85 ° ≦ {\sum }_{n = 1}^{N} ( Δ {θ}_{D , n} - Δ {θ}_{T , n} ) + {θ}_{0} ≦ 95 ° & ( 1 )\end{matrix}$$

5. The processing method of claim 4,
wherein processing conditions in the forming of the deposit and in the removing of the part of the mask film and/or the part of the deposit are adjusted to satisfy the expression (1).

6. The processing method of claim 5,
wherein the processing conditions are at least one of processing times of the forming of the deposit and the removing of the part of the mask film and/or the part of the deposit, a flow rate ratio of the first gas to the second gas in the forming of the deposit, or a flow rate ratio of the first gas to the second gas in the removing of the part of the mask film and/or the part of the deposit.

7. The processing method of claim 5,
wherein the processing conditions are same in the forming of the deposit and the removing of the part of the mask film and/or the part of the deposit except a flow rate ratio of the first gas to the second gas.

8. The processing method of claim 1,
wherein the first gas includes a gas which generates a precursor configured to form the deposit on the etching target film by plasma.

9. The processing method of claim 1,
wherein the first gas includes at least one of a hydrocarbon (CH) gas, a hydrofluorocarbon (CHF) gas or a fluorocarbon (CF) gas.

10. The processing method of claim 1,
wherein the second gas includes a gas which generates a precursor configured to remove the deposit formed on the etching target film by plasma.

11. The processing method of claim 1,
wherein the second gas includes an oxygen-containing gas at least.

12. The processing method of claim 11,
wherein the oxygen-containing gas includes at least one of an oxygen (O₂) gas, a carbon dioxide (CO₂) gas, a carbon monoxide (CO) gas or an ozone (O₃) gas.

13. The processing method of claim 1, further comprising:
treating the mask film by plasma of a hydrogen (H₂) gas or plasma of a hydrogen bromide (HBr) gas before the forming of the deposit and the removing of the part of the mask film and/or the part of the deposit.

14. The processing method of claim 1, further comprising:
etching the etching target film through the mask film after performing the forming of the deposit and the removing of the part of the mask film and/or the part of the deposit a preset number of times.

15. The processing method of claim 1,
wherein when a repetition number of the forming of the deposit and the removing of the part of the mask film and/or the part of the deposit is equal to or larger than 2, a processing condition for an n^{th} forming of the deposit and a processing condition for an (n+1)^{th} forming of the deposit are same.

16. The processing method of claim 1,
wherein when a repetition number of the forming of the deposit and the removing of the part of the mask film and/or the part of the deposit is equal to or larger than 2, a processing condition for an n^{th} forming of the deposit and a processing condition for an (n+1)^{th} forming of the deposit are different.

17. The processing method of claim 1,
wherein when a repetition number of the forming of the deposit and the removing of the part of the mask film and/or the part of the deposit is equal to or larger than 2, a processing condition for an n^{th} removing of the part of the mask film and/or the part of the deposit and a processing condition for an (n+1)^{th} removing of the part of the mask film and/or the part of the deposit are same.

18. The processing method of claim 1,
wherein when a repetition number of the forming of the deposit and the removing of the part of the mask film and/or the part of the deposit is equal to or larger than 2, a processing condition for an n^{th} removing of the part of the mask film and/or the part of the deposit and a processing condition for an (n+1)^{th} removing of the part of the mask film and/or the part of the deposit are different.

19. A substrate processing apparatus, comprising:
a placing table configured to place a substrate thereon; and
a controller,
wherein the controller performs:
placing, on the placing table, the substrate having a mask film on an etching target film;
forming a deposit on the mask film by plasma of a processing gas which includes a first gas and a second gas and in which a flow rate ratio R1 of the first gas to the second gas is controlled; and
removing a part of the mask film and/or a part of the deposit by plasma of a processing gas which is a same kind as the processing gas used in the forming of the deposit and in which a flow rate ratio R2 of the first gas to the second gas is controlled to satisfy R2<R1, and
wherein the controller controls a taper angle of a side surface of a pattern of the mask film to a required value by repeating the forming of the deposit and the removing of the part of the mask film and/or the part of the deposit a preset number of times.
